(19) United States
(12) Patent Application Publication
(10) Pub. No.: US 2008/0150047 A1
(43) Pub. Date: Jun. 26, 2008

(54) GATE INSULATING LAYER IN A SEMICONDUCTOR DEVICE AND METHOD OF FORMING THE SAME

(75) Inventor: Sang-Cheol BANG, Seoul (KR)

Correspondence Address: WORKMAN NYDEGGER, 60 EAST SOUTH TEMPLE, 1000 EAGLE GATE TOWER, SALT LAKE CITY, UT, 84111, US

(73) Assignee: DONGBU HITEK CO., LTD., Seoul (KR)

(21) Appl. No.: 11/951,834

(22) Filed: Dec. 6, 2007

(30) Foreign Application Priority Data
Dec. 26, 2006 (KR) 10-2006-0133455

(51) Int. Cl. H01L 29/78; H01L 21/314; H01L 21/283

(52) U.S. Cl. 257/411; 438/763; 438/591; 257/E29.255; 257/E21.177; 257/E21.24

(57) ABSTRACT

A gate insulating layer in a semiconductor device and a method of forming the same. In one example embodiment, a gate insulating layer in a semiconductor device includes an oxide layer, a first oxynitride layer formed between a semiconductor substrate and the oxide layer, and a second oxynitride layer formed on the oxide layer.

### CROSS-REFERENCE TO RELATED APPLICATION

This application claims priority to Korean Patent Application No. 10-2006-0133455, filed on Dec. 26, 2006, which is incorporated herein by reference in its entirety.

### BACKGROUND

1. Field of the Invention

The present invention relates, in general, to a gate insulating layer in a semiconductor device and, more particularly, to a gate insulating layer in a semiconductor device and a method of forming the same that is capable of improving the gate oxide integrity (GOI) and the overall reliability of the semiconductor device.

2. Description of the Related Art

In general, a transistor for dynamic random access memory (DRAM) devices and logic devices includes a gate oxide layer separated from a substrate by a gate electrode. In a memory cell of a memory device, such as a flash memory device, a tunnel oxide layer is also typically formed between a floating gate and a substrate.

In recent years, efforts to improve the characteristics of gate oxide layers or tunnel oxide layers have included forming the gate oxide layers or the tunnel oxide layers using an oxynitride layer containing nitrogen. The gate oxide layer is formed from the oxynitride layer and the tunnel oxide layer is referred to as the gate insulating layer.

The gate insulating layer serves to reduce the leakage current of the insulating layer and the occurrence of defects within the insulating layer, and also improves a degradation phenomenon of a channel hot electron effect. Further, in the event that the gate electrode to be formed on the gate insulating layer is formed of a polysilicon layer doped with a P+ type impurity ion, such as boron (B), the gate insulating layer can prevent boron (B) from the gate electrode from infiltrating into a channel region in a subsequent annealing process.

The gate insulating layer is generally formed using nitrous oxide (N₂O) or nitric oxide (NO) gas, in which case the distributions of nitrogen (N) are concentrated on the interface of the silicon substrate and the insulating layer. Although the distributions of nitrogen (N) can improve the hot electron degradation phenomenon, they are generally ineffective at preventing boron (B) from infiltrating into the silicon substrate. Where a high concentration of nitrogen (N) exists at the interface of the silicon substrate, the GOI and other device characteristics are degraded due to the effects of the high concentration, such as the channel carrier mobility being degraded and an increase in shift in the threshold voltage. Furthermore, where borondifluoride (BF₂) is implanted to form P+ source/drain regions, boron (B) diffusion results because fluorine (F) moves to the interface of the substrate and the gate insulating layer.

### SUMMARY OF EXAMPLE EMBODIMENTS

In general, example embodiments of the invention relate to a gate insulating layer in a semiconductor device and a method of forming the same. The example gate insulating layer disclosed herein includes an oxide layer formed between oxynitride layers. The example gate insulating layer reduces or prevents the infiltration of boron (B) and reduces or prevents a hot carrier effect, thus improving the gate oxide integrity (GOI) and overall reliability of the semiconductor device. The example gate insulating layer may also exhibit an improved interfacial characteristic under a semiconductor substrate.

In one example embodiment, a gate insulating layer in a semiconductor device includes an oxide layer and first and second oxynitride layers. The first oxynitride layer is formed between a semiconductor substrate and the oxide layer. The second oxynitride layer is formed on the oxide layer.

In another example embodiment, a method of forming a gate insulating layer of a semiconductor device includes forming an oxide layer, forming a first oxynitride layer, and forming a second oxynitride layer. The oxide layer is formed on an interface of a semiconductor substrate. The first oxynitride layer is formed between the semiconductor substrate and the oxide layer. The second oxynitride layer is formed on the oxide layer.

### BRIEF DESCRIPTION OF THE DRAWINGS

Aspects of example embodiments of the invention will become apparent from the following description of example embodiments given in conjunction with the accompanying drawings, in which:

FIGS. 1A-1C are cross-sectional views of an example gate insulating layer in an example semiconductor device; and

FIG. 2 is a flowchart disclosing an example method of forming the example gate insulating layer of FIGS. 1A-1C.

### DETAILED DESCRIPTION OF EXAMPLE EMBODIMENTS

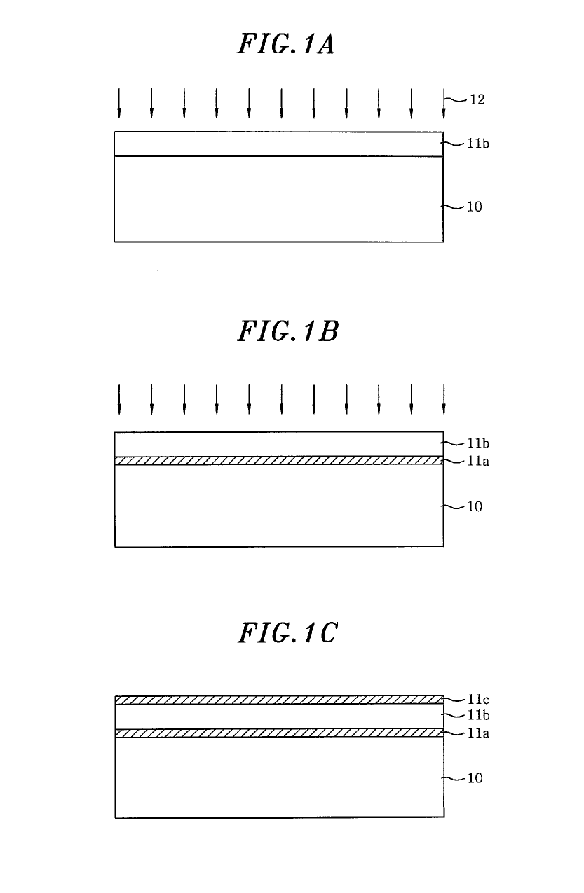

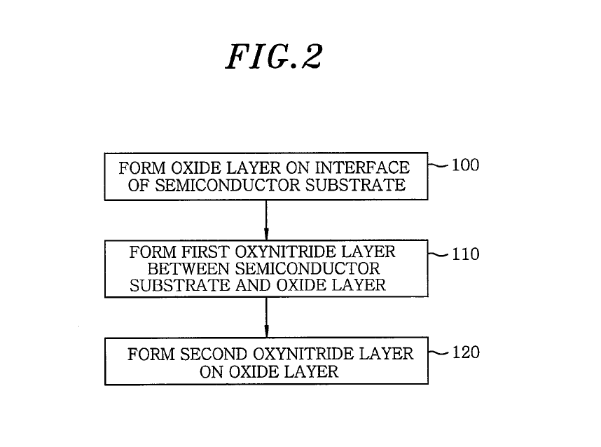

Hereinafter, example embodiments of the invention will be described in detail with reference to the accompanying drawings. FIGS. 1A-1C are cross-sectional views of an example gate insulating layer in an example semiconductor device. FIG. 2 is a flowchart disclosing an example method of forming the example gate insulating layer of FIGS. 1A-1C.

Referring first to FIGS. 1A-1C, an example gate insulating layer 11 in an example semiconductor device is disclosed. The example gate insulating layer 11 includes an oxide layer 11b positioned between first and second oxynitride layers 11a and 11c. The gate insulating layer 11 therefore has a stack structure including, from bottom to top, the first oxynitride layer 11a, the oxide layer 11b, and the second oxynitride layer 11c. The first oxynitride layer 11a is formed between a semiconductor substrate 10 and the oxide layer 11b, and the second oxynitride layer 11c is formed on the oxide layer 11b, or between the oxide layer 11b and a polysilicon layer for a gate electrode (not shown).

The first oxynitride layer 11a improves a degradation phenomenon of a channel hot electron effect and also reduces or prevents the diffusion of fluorine (F) at the interface of the semiconductor substrate 10 and the gate insulating layer 11. Meanwhile, the second oxynitride layer 11c reduces or prevents boron (B) ions, doped into a polysilicon layer (not shown), from infiltrating into the semiconductor substrate 10 through the gate insulating layer 11. The second oxynitride layer 11c minimizes a shift in the threshold voltage. As the nitrogen (N) distributions within the gate insulating layer 11 are spaced apart from the interface of the silicon substrate 10, the effect on the shift in the threshold voltage is decreased.

With reference now to FIG. 2, an example method of forming the example gate insulating layer 11 will now be disclosed with continuing reference to FIGS. 1A-1C.

At 100, an oxide layer is formed on an interface of a semiconductor substrate. For example, as disclosed in FIG. 1A, the silicon oxide layer 11b may be grown by first forming a sacrificial oxide layer (not shown) on the semiconductor substrate, performing a well formation process and a channel ion implantation process for V^{th} control, and performing an oxidization process on the semiconductor substrate 10 from which the sacrificial oxide layer has been removed. The silicon oxide layer 11b may be formed with a thickness between about 10 angstroms and about 100 angstroms by a thermal oxidization process.

At 110, a first oxynitride layer is formed between a semiconductor substrate and the oxide layer. For example, as disclosed in FIG. 1B, the first oxynitride layer 11a may be formed at the interface of the silicon oxide layer 11b and the semiconductor substrate 10 by chemical vapor deposition (CVD). The first oxynitride layer 11a may be deposited with a thickness of about 8 angstroms to about 12 angstrom at a temperature between about 800° C. and about 1100° C.

At 120, a second oxynitride layer is formed on the oxide layer. For example, as disclosed in FIG. 1C, the second oxynitride layer 11c may be formed on the silicon oxide layer 11b. The second oxynitride layer 11a may be deposited with a thickness of about 8 angstroms to about 12 angstroms at a temperature between about 800° C. and about 1100° C.

A polysilicon layer for s gate electrode may also be formed on the gate insulating layer 11 (not shown). The polysilicon layer may be doped with an N type impurity ion or a P type impurity ion.

As described above, the example gate insulating layer has an oxide layer formed between oxynitride layers. Accordingly, the infiltration of boron (B) can be reduced or prevented, the GOI and the overall reliability of devices can be improved through the prevention of a hot carrier effect, and an interfacial characteristic under a semiconductor substrate can be improved.

While example embodiments of the invention have been shown and described herein, various changes and modifications may be made to these example embodiments. These example embodiments are therefore not limiting of the scope of the claims.

What is claimed is:

1. A gate insulating layer in a semiconductor device, comprising:
an oxide layer;
a first oxynitride layer formed between a semiconductor substrate and the oxide layer; and
a second oxynitride layer formed on the oxide layer.

2. The gate insulating layer of claim 1, wherein the oxide layer has a thickness between about 10 angstroms to about 100 angstroms.

3. The gate insulating layer of claim 1, wherein the first oxynitride layer has a thickness between about 8 angstroms and about 12 angstroms.

4. The gate insulating layer of claim 1, wherein the second oxynitride layer has a thickness between about 8 angstroms and about 12 angstroms.

5. A semiconductor device comprising:
a semiconductor substrate;
the gate insulating layer of claim 1 formed on the semiconductor substrate; and
a polysilicon layer for a gate electrode formed on the gate insulating layer.

6. The semiconductor device of claim 5, wherein the polysilicon layer is doped with an N type impurity ion or a P type impurity ion.

7. A method of forming a gate insulating layer in a semiconductor device, comprising the acts of:
forming an oxide layer on an interface of a semiconductor substrate;
forming a first oxynitride layer between the semiconductor substrate and the oxide layer; and
forming a second oxynitride layer on the oxide layer.

8. The method of claim 7, wherein the layers of the gate insulating layer are formed by chemical vapor deposition (CVD).

9. The method of claim 7, wherein the oxide layer is formed by a thermal oxidization process.

10. The method of claim 7, wherein the first oxynitride layer is formed with a thickness between about 8 angstroms and about 12 angstroms.

11. The method of claim 7, wherein the first oxynitride layer is formed at a temperature between about 800° C. and about 100° C.

12. The method of claim 7, wherein the second oxynitride layer is formed with a thickness between about 8 angstroms and about 12 angstroms.

13. The method of claim 7, wherein the second oxynitride layer is formed at a temperature between about 800° C. and about 100° C.

14. The method of claim 7, wherein the act of forming an oxide layer on an interface of a semiconductor substrate comprises the acts of:
forming a sacrificial oxide layer (not shown) on the semiconductor substrate;
performing a well formation process and a channel ion implantation process; and
performing an oxidization process on the semiconductor substrate from which the sacrificial oxide layer has been removed.

15. A method of forming a semiconductor device, comprising the acts of:
forming the gate insulating layer according to claim 7; and
forming a polysilicon layer for a gate electrode on the gate insulating layer.
